(19) United States
(12) Patent Application Publication
(10) Pub. No.: US 2016/0148884 A1
(43) Pub. Date: May 26, 2016

(54) MEMORY APPARATUS HAVING POWER PAD

(71) Applicant: SK hynix Inc., Gyeonggi-do (KR)

(72) Inventor: Youn Cheul KIM, San Jose, CA (US)

(21) Appl. No.: 14/550,577

(22) Filed: Nov. 21, 2014

(51) Int. Cl. H01L 23/00; G11C 29/12; H01L 23/60; G11C 5/14

(52) U.S. Cl. CPC H01L 24/06; G11C 5/14; G11C 29/1201; H01L 23/60; H01L 2224/06515; H01L 2924/1434; H01L 2924/13091; H01L 2924/1304

(57) ABSTRACT

A memory apparatus includes a pad, an internal circuit that is connected with the pad, a power connection unit connected with power meshes, and a first switching unit suitable for selectively connecting the pad with the power connection unit based on a package control signal.

### FIELD OF THE INVENTION

Various embodiments of the present invention generally relate to a semiconductor apparatus and, more particularly, to a power supply for a memory apparatus.

### BACKGROUND

In general, memory apparatuses include power pads and operate by using power received through the power pads from an exterior source. A memory apparatus may use power provided from the exterior as it is and may generate internal power by adjusting (i.e., boosting or dropping) the power provided from the exterior. As the current trend is towards lower power consumption, reception of power with a constant and stable voltage level is important.

Further, a memory apparatus is designed to operate with various data bandwidths according to applications to improve compatibility and reduce manufacturing costs. For example, a memory apparatus in an electronic device, such as a server or a desktop, operates with a data bandwidth corresponding to X4 or X8, and a memory apparatus to be used in a notebook (or a laptop), a mobile product or a graphic product operates with a data bandwidth corresponding to X16. In this regard, to control the data bandwidth of a memory apparatus according to applications, the memory apparatus includes one or more option pads. To designate data bandwidth, the option pads may be bonded to receive a specified combination of voltages.

### SUMMARY

Various embodiments of the present invention are directed to a memory apparatus capable of utilizing at least one of an option pad and a probing pad, as a power pad.

In an embodiment of the present invention, a memory apparatus may include: a pad; an internal circuit operating connected with the pad; a power connection unit connected with power meshes; and a first switching unit suitable for selectively connecting the pad with the power connection unit based on a package control signal.

In an embodiment of the present invention, a memory apparatus may include : a first pad; a first power switching unit suitable for connecting the first pad with a first power supply voltage mesh or a second power supply voltage mesh based on a signal, which is inputted through the first pad; a second pad; and a second power switching unit suitable for connecting the second pad with the first power supply voltage mesh or the second power supply voltage mesh based on a signal, which is inputted through the second pad.

In an embodiment of the present invention, a memory apparatus may include: a pad; an internal circuit operating by using a signal, which is received through the pad; and a power switching unit suitable for connecting the pad with a first power supply voltage mesh or a second power supply voltage mesh based on the signal.

According to the embodiments of the present invention, since the number of pads for receiving power may be increased, constant and stable power may be supplied to a memory apparatus.

### BRIEF DESCRIPTION OF THE DRAWINGS

FIG. 1 is a diagram illustrating a memory apparatus.

FIG. 2 is a diagram illustrating a memory apparatus in accordance with an embodiment of the present invention.

FIG. 3 is a detailed diagram of a power connection unit shown in FIG. 2.

FIG. 4 is a diagram illustrating a memory apparatus in accordance with an embodiment of the present invention.

FIG. 5 is a diagram illustrating a graphic system in accordance with an embodiment of the present invention.

### DETAILED DESCRIPTION

A memory apparatus capable of receiving power through pads will be described below with reference to the accompanying drawings through various examples of embodiments. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numeral's correspond directly to like parts in the various figures and embodiments of the present invention.

The drawings are not necessarily to scale and, in some instances, proportions may have been exaggerated in order to dearly illustrate features of the embodiments. In this specification, specific terms have been used. The terms are used to describe the present invention and are not used to qualify the sense or limit the scope of the present invention.

It is also noted that in this specification, ‘and/or’ represents that one or more of components arranged before and after ‘and/or’ is included. Furthermore, “connected/coupled” refers to one component not only directly coupling another component but also indirectly coupling another component through an intermediate component. In addition, a singular form may include a plural form as long as it is not specifically mentioned in a sentence. Furthermore, ‘include/comprise’ or ‘including/comprising’ used in the specification represents that one or more components, steps, operations, and elements exist or are added.

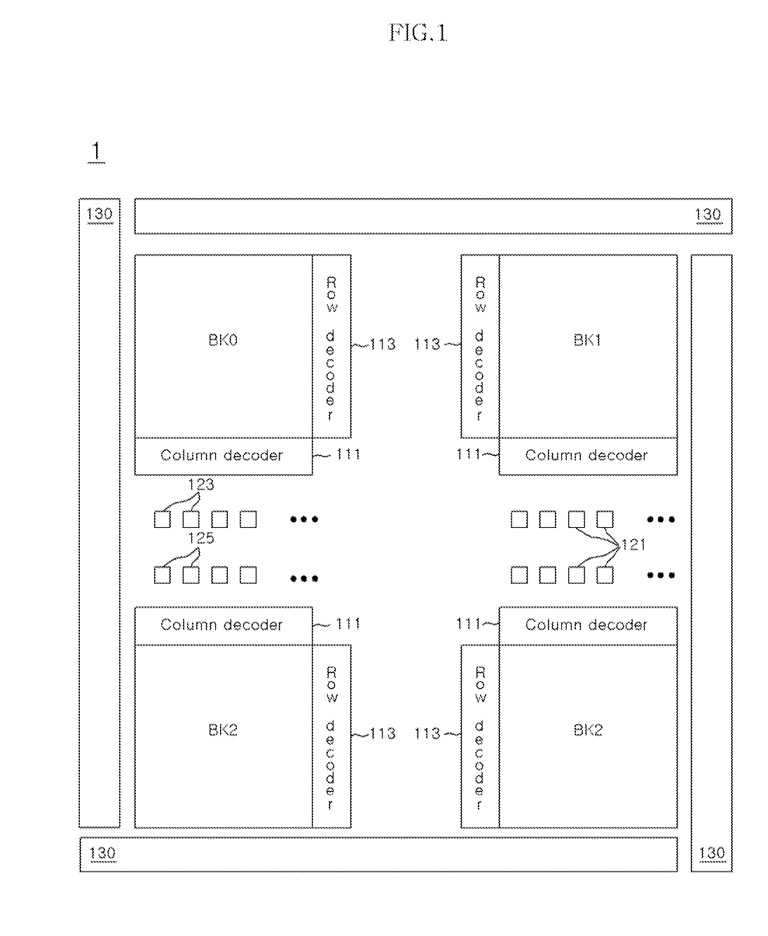

FIG. 1 is a diagram illustrating a memory apparatus 1. In FIG. 1, the memory apparatus 1 may include a plurality of memory banks BK0, BK1, BK2 and BK3 and a plurality of pads. A plurality of word lines and a plurality of bit lines are disposed in the respective memory banks BK0, BK1, BK2 and BK3, and memory cells are disposed at crossing points of the word lines and the bit lines. The memory cells may store data. Each of the memory banks BK0, BK1, BK2 and BK3 may include a column decoder 111 for selectively accessing the bit lines and a row decoder 113 for selectively accessing the word lines.

Data lines (or data buses) and data input/output control circuits may be disposed in the space among the memory banks BK0, BK1, BK2 and BK3. This space is referred to as the peripheral region. The pads may be disposed in the peripheral region. While it is illustrated in FIG. 1 that the pads are disposed in two rows, this is not intended to be a limitation and the pads may be arranged in a different order or shape. The pads may be used for various functions. For example, the memory apparatus 1 may perform a data input/output operation by receiving a command signal, an address signal, data and a clock signal from an external (e.g., a memory controller). The pads may include a command pad, an address pad, a clock pad and a data pad for receiving the command signal, the address signal, the clock signal and the data which are transmitted from the external.

The pads may further include power pads 121, option pads 123, and probing pads 125. The power pads 121 may receive power used for the memory device 1 to operate, from an external power supply device. The power supplied from the external power supply device may include a first power supply voltage and a second power supply voltage. The first power supply voltage may be a high voltage (e.g., VDD), and the second power supply voltage may be a low voltage or a ground voltage (e.g., VSS). Power meshes 130 may be disposed in the entire region of the memory apparatus 1. The power meshes 130 are connected with the power pads 121, and play the role of supplying power to the entire region of the memory apparatus 1. The power meshes 130 may provide power supply voltages needed to operate all internal circuits which may be included in the memory apparatus 1.

The option pads 123 may be used to determine the data bandwidth of the memory apparatus 1. In general, the option pads 123 may be bonded to receive specified voltage levels when the memory apparatus 1 is packaged. The memory apparatus 1 may operate with various data bandwidths according to combinations of the specified voltage levels inputted through the option pads 123. For example, at least two option pads 123 may be disposed. When two low level voltages are received through the option pads 123, the memory apparatus 1 may operate with a X16 data bandwidth. When one low level voltage and one high level voltage are received through the option pads 123, the memory apparatus 1 may operate with a X8 data bandwidth. Moreover, when two high level voltages are received through the option pads 123, the memory apparatus 1 may operate with a X4 data bandwidth. Although the levels of the signals received by the option pads 123 are described as an example to designate the data bandwidth of the memory apparatus 1, the embodiments of the present invention are not limited to the above-described cases, and it is to be noted that the number of option pads 123 may be increased or the levels of the signals received by the option pads 123 may be changed.

The probing pads 125 may be disposed for a test of the memory apparatus 1. The memory apparatus 1 is manufactured on a wafer, and a test for the memory apparatus 1 may be performed at a wafer level. If the test is completed, the memory apparatus 1 of the wafer level may be packaged. The probing pads 125 may be connected with an external device such as test equipment at the wafer level, and may transmit control signals to the memory apparatus 1 or output the signals generated in the internal circuits of the memory apparatus 1, to the external device. If the test is completed at the wafer level and the memory apparatus 1 is packaged, the probing pads 125 may not be needed again. That is to say, the probing pads 125 are not necessary when the memory apparatus 1 performs normal operations. The normal operations may include various operations which are performed by the memory apparatus 1. The normal operations may include a data write operation, a data read operation, a test operation at a package level, a refresh operation, and so forth.

The option pads 123 and the probing pads 125 of the memory apparatus 1 may respectively receive a first power supply voltage and a second power supply voltage when the memory apparatus 1 is packaged. In other words, the option pads 123 and the probing pads 125 may be bonded with external power supply terminals. Therefore, the option pads 123 and the probing pads 125 may be used as power pads for receiving the first and second power supply voltages, after the memory apparatus 1 is packaged.

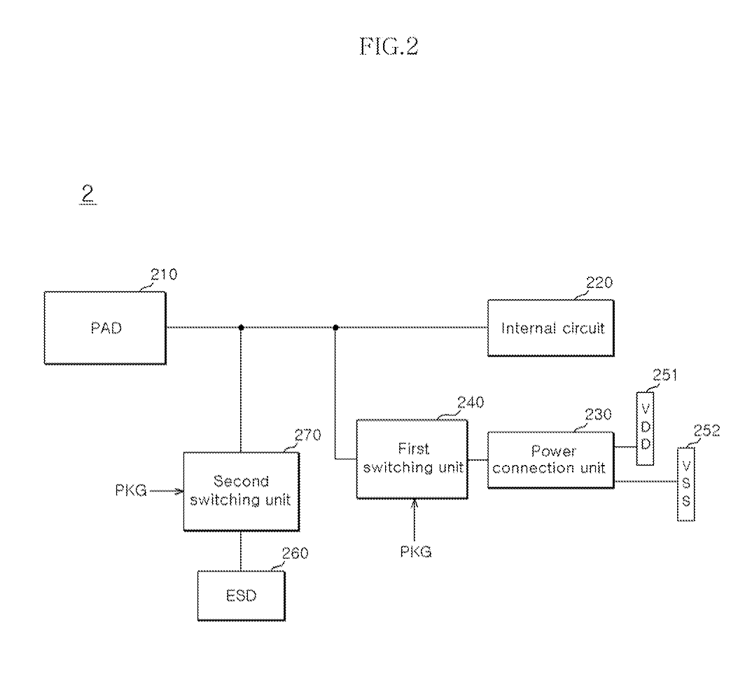

FIG. 2 is a diagram illustrating a memory apparatus 2 in accordance with an embodiment of the present invention. In FIG. 2, the memory apparatus 2 may include a pad 210, an internal circuit 220, a power connection unit 230, and a first switching unit 240. The pad 210 may be any one of a probing pad and an option pad. The internal circuit 220 may be any circuit which is disposed to perform an operation of the memory apparatus 2. For example, if the pad 210 is a probing pad, the internal circuit 220 may be a circuit for performing a wafer level test of the memory apparatus 2. If the pad 210 is an option pad, the internal circuit 220 may be a decoding circuit for decoding the signal received through option pads (including the pad 210) and determining the data bandwidth of the memory apparatus 2. The power connection unit 230 may be selectively connected with a plurality of power meshes 251 and 252 in response to the signal received through the pad 210.

The first switching unit 240 may be connected with the pad 210 and the internal circuit 220, and may be selectively connected with the power connection unit 230. The first switching unit 240 may selectively connect the power connection unit 230 with the pad 210 in response to a package control signal PKG. The package control signal PKG may be deactivated at a wafer level and may be activated at a package level. Namely, the package control signal PKG, as a signal having information on whether the memory apparatus 2 is at the wafer level or is packaged, may be inputted from an external or may be internally generated after the memory apparatus 2 is packaged. The first switching unit 240 may disconnect the pad 210 from the power connection unit 230 when the package control signal PKG is deactivated, and may connect the pad 210 with the power connection unit 230 when the package control signal PKG is activated.

In FIG. 2, the power meshes may include a first power supply voltage mesh 251 and a second power supply voltage mesh 252. When connected with the pad 210 through the first switching unit 240, the power connection unit 230 may connect the pad 210 with one of the first and second power supply voltage meshes 251 and 252 in response to the signal inputted through the pad 210. The first power supply voltage may be a high voltage (e.g. VDD) and the second power supply voltage may be a low voltage or a ground voltage (e.g., VSS).

In FIG. 2, the memory apparatus 2 may further include an electrostatic discharge (ESD) circuit 260, and a second switching unit 270. The ESD circuit 260 may remove the power noise applied to the pad 210 and stabilize a voltage level of a signal which is received from the pad 210. The second switching unit 270 may selectively connect the ESD circuit 260 with the pad 210 in response to the package control signal PKG. The second switching unit 270 may disconnect the ESD circuit 260 from the pad 210 when the package control signal PKG is deactivated, and may connect the ESD circuit 260 with the pad 210 when the package control signal PKG is activated. When the package control signal PKG is deactivated, the memory apparatus 2 may receive a control signal through the pad 210 or may output the signal generated in the memory apparatus 2 through the pad 210, for probe detection. Thus, when the memory apparatus 2 is at the wafer level, the pad 210 does not need to be connected with the ESD circuit 260. However, when the memory apparatus 2 is packaged and the pad 210 receives any one of first and second power supply voltages, the operation of removing the noise of the first or second power supply voltage or stabilizing the voltage level thereof is inevitably needed. Hence, the second switching unit 270 selectively connects the pad 210 and the ESD circuit 260 according to the package control signal PKG, thereby allowing the memory apparatus 2 to perform a stable and precise operation.

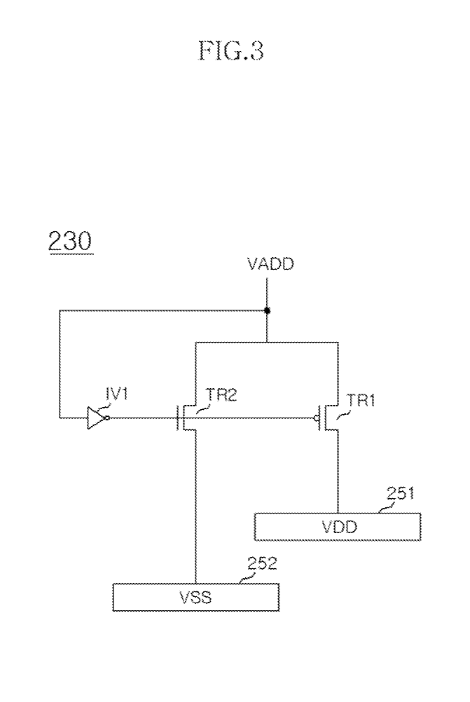

FIG. 3 is a detailed diagram of the power connection unit 230 shown in FIG. 2. In FIG. 3, the power connection unit 230 may include an inverter IV1, a first transistor TR1, and a second transistor TR2. The inverter IV1 inverts a signal VADD which is received through the pad 210. The signal VADD may be one of the first power supply voltage and the second power supply voltage. The first transistor TR1 has a gate receiving the output of the inverter IV1, a drain receiving the signal VADD, and a source connected with the first power supply voltage mesh 251. The first transistor TR1 may be turned on when the pad 210 receives the first power supply voltage, and may supply the first power supply voltage inputted through the pad 210, to the first power supply voltage mesh 251. The second transistor TR2 has a gate receiving the output of the inverter IV1, a drain receiving the signal VADD, and a source connected with the second power supply voltage mesh 252. The second transistor TR2 may be turned on when the pad 210 receives the second power supply voltage, and may supply the second power supply voltage inputted through the pad 210, to the second power supply voltage mesh 252. The first transistor TR1 may be a P channel MOS transistor, and the second transistor TR2 may be an N channel MOS transistor.

When the memory apparatus 2 is at the wafer level, the package control signal PKG may be deactivated, and the first switching unit 240 may disconnect the pad 210 and the power connection unit 230. Also, the second switching unit 270 may disconnect the pad 210 and the ESD circuit 260. The pad 210 may receive a control signal through an external device such as test equipment, and may transmit the control signal to the internal circuit 220. As a test operation is performed, the signal generated by the internal circuit 220 may be outputted through the pad 210, and the external device may receive the signal by performing probe detection for the pad 210.

If the memory apparatus 2 is packaged, the package control signal PKG may be activated, and the first switching unit 240 may connect the pad 210 and the power connection unit 230. If the pad 210 is bonded with an external voltage supply terminal' to receive the first power supply voltage, the power connection unit 230 may receive the first power supply voltage through the pad 210. Accordingly, the first transistor TR1 may be turned on, and the first power supply voltage may be supplied to the first power supply voltage mesh 251. If the pad 210 is bonded with an external voltage supply terminal to receive the second power supply voltage, the power connection unit 230 may receive the second power supply voltage through the pad 210. Accordingly, the second transistor TR2 may be turned on, and the second power supply voltage may be supplied to the second power supply voltage mesh 252. The memory apparatus 2 may additionally receive the first or second power supply voltage through the pad 210, which is used as the option pad or the probing pad, and the first or second power supply voltage received through the pad 210 may be supplied to the first or second power supply voltage mesh 251 or 252 and be used as the power of the internal circuit of the memory apparatus 2.

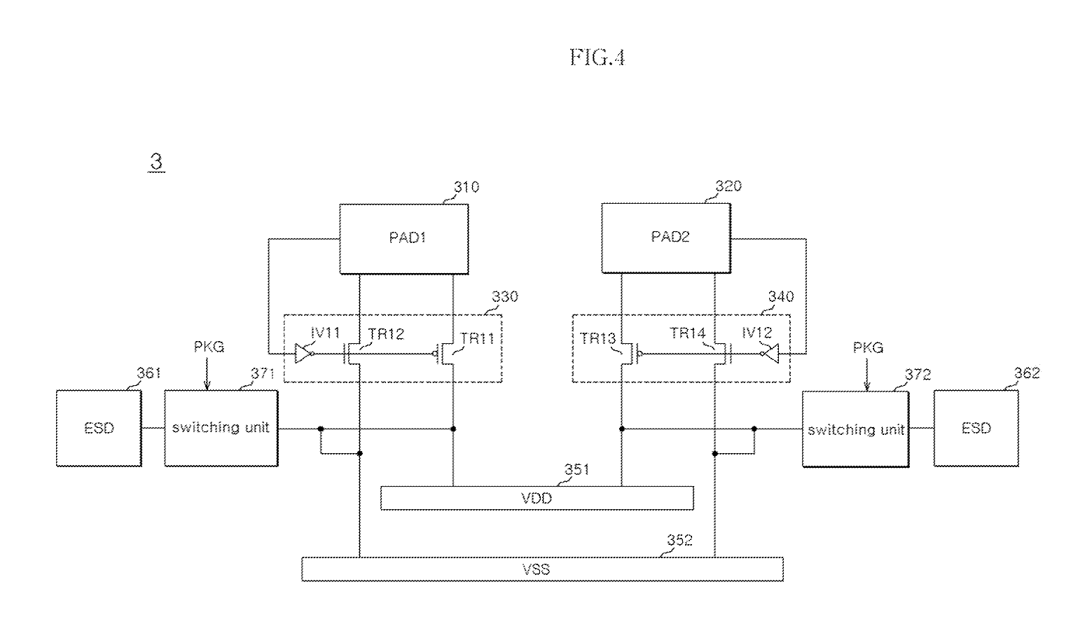

FIG. 4 is a diagram illustrating a memory apparatus 3 in accordance with an embodiment of the present invention. In FIG. 4, the memory apparatus 3 may include a first pad 310 a second pad 320, a first power switching unit 330, and a second power switching unit 340. Each of the first and second pads 310 and 320 may be any one of an option pad and a probing pad. When the memory apparatus 3 is packaged, each of the first and second pads 310 and 320 may be bonded with an external voltage supply terminal which supplies one of a first power supply voltage and a second power supply voltage.

The first power switching unit 330 may connect the first pad 310 with one of a first power supply voltage mesh 351 and a second power supply voltage mesh 352 in response to a signal which is received through the first pad 310. Similarly, the second power switching unit 340 may connect the second pad 320 with one of the first power supply voltage mesh 351 and the second power supply voltage mesh 352 in response to a signal which is received through the second pad 320.

Each of the first and second power switching units 330 and 340 may have a configuration similar to the power connection unit 230 shown in FIG. 3. The first power switching unit 330 may include a first inverter IV11, a first transistor TR11, and a second transistor TR12. The first inverter IV11 is connected with the first pad 310, and inverts the signal which is received through the first pad 310. The first transistor TR11 has a gate receiving the output of the first inverter IV11, a drain connected with the first pad 310, and a source connected with the first power supply voltage mesh 351. The second transistor TR12 has a gate receiving the output of the first inverter IV11, a drain connected with the first pad 310, and a source connected with the second power supply voltage mesh 352. The first transistor TR11 may be a P channel MOS transistor, and the second transistor TR12 may be an N channel MOS transistor.

If the first pad 310 is bonded with an external voltage supply terminal to receive the first power supply voltage, the first transistor TR11 may be turned on and connect the first pad 310 with the first power supply voltage mesh 351. Further, if the first pad 310 is bonded with an external voltage supply terminal to receive the second power supply voltage, the second transistor TR12 may be turned on and connect the first pad 310 with the second power supply voltage mesh 352.

The second power switching unit 340 may include a second inverter IV12, a third transistor TR13, and a fourth transistor TR14. The second inverter IV12 is connected with the second pad 320, and inverts the signal which is received through the second pad 320. The third transistor TR13 has a gate receiving the output of the second inverter IV12, a drain connected with the second pad 320, and a source connected with the first power supply voltage mesh 351. The fourth transistor TR14 has a gate receiving the output of the second inverter IV12, a drain connected with the second pad 320, and a source connected with the second power supply voltage mesh 352. The third transistor TR13 may be a P channel MOS transistor, and the fourth transistor TR14 may be an N channel MOS transistor.

If the second pad 320 is bonded with an external voltage supply terminal to receive the first power supply voltage, the third transistor TR13 may be turned on and connect the second pad 320 with the first power supply voltage mesh 351. Further, if the second pad 320 is bonded with an external voltage supply terminal to receive the second power supply voltage, the fourth transistor TR14 may turn on and connect the second pad 320 with the second power supply voltage mesh 352. plurality of ESD circuits 361 and 362 and a plurality of switching units 371 and 372. The ESD circuits 361 and 362 may be connected with the first and second pads 310 and 320 through the switching units 371 and 372, respectively. The switching units 371 and 372 may selectively connect the ESD circuits 361 and 362 with the first and second pads 310 and 320 in response to a package control signal PKG. While it is illustrated in FIG. 4 that the ESD circuit 361 is connected with the first pad 310 through the switching unit 371 between the first and second transistors TR11 and TR12 and the first and second power supply voltage meshes 351 and 352, the present invention is not limited to such, and it is to be noted that the ESD circuit 361 may be changed to be connected with the first pad 310 through the switching unit 371 between the first pad 310 and the first and second transistors TR11 and TR12. Similarly, it is to be noted that the ESD circuit 362 may be changed to be connected with the second pad 320 through the switching unit 372 between the second pad 320 and the third and fourth transistors TR13 and TR14.

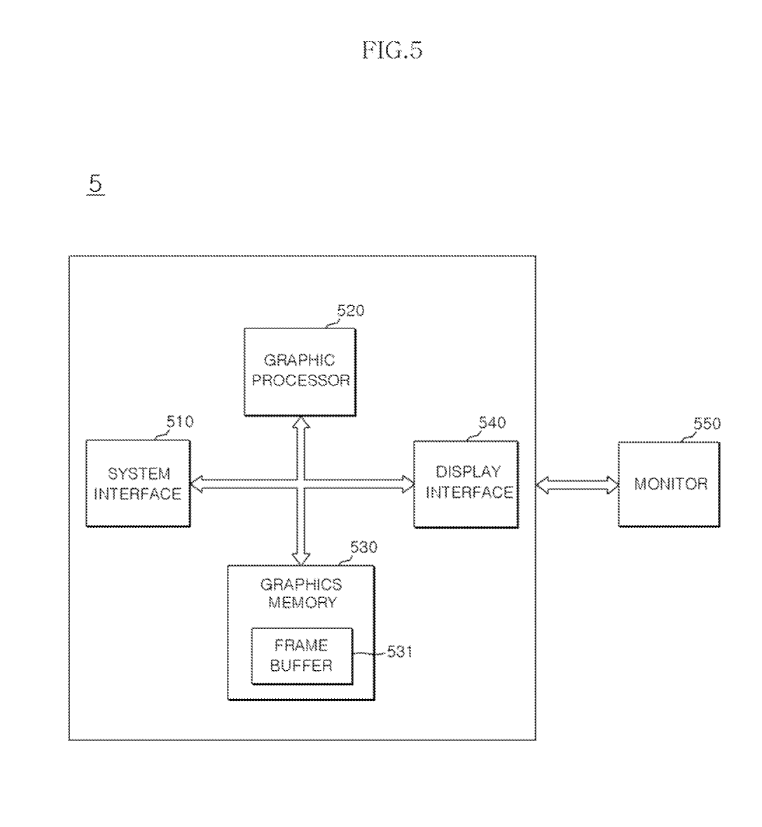

FIG. 5 is a diagram illustrating a graphic system 5 in accordance with an embodiment of the present invention. In FIG. 5, the graphic system 5 may include a system interface 510, a graphic processor 520, a graphics memory 530, and a display interface 540. The graphic system 5 may be connected with the system interface 510 which includes a peripheral component interface (PCI), a peripheral component interface express (PCI-Express) or an accelerated graphics port interface (AGPI) bus, and may be connected with the central processing (not shown) of a computer system.

The graphic processor 520 may generate a computer graphic in response to a software program which is executed in the central processing unit of the computer system. The graphic processor 520 may generate a data structure or a command list for representing an object to be displayed. The graphics memory 530 may store the data structure or the command list which is generated by the graphic processor 520. Accordingly, the graphic processor 520 may generate pixel data for display, by quickly reading and processing the data stored in the graphics memory 530. The graphics memory 530 may include a frame buffer 531, and the graphic processor 520 may write the pixel data to the frame buffer 531 in the graphics memory 530.

The display interface 540 may receive the pixel data outputted from the frame buffer 531, and may generate control signal's and data for displaying an image on a monitor 550. The display interface 540 may provide the control signals and data generated based on the pixel data, to a display port such as a video graphics array (VGA), a digital visual interface (DVI) and a high definition multimedia interface (HEMI), such that an image may be displayed on the monitor 550.

In particular, the graphics memory 530 may be used as the working memory of the graphic processor 520. The graphics memory 530 may include the memory apparatuses 1, 2 and 3 shown in FIGS. 1 to 4. The graphics memory 530 may include an option pad for determining data bandwidth with which the graphics memory 530 operates, and the option pad may be connected with a power supply voltage mesh in the graphics memory 530, according to a voltage level which is received as the option pad is bonded. Also, the graphics memory 530 may include a probing pad for a wafer level test of the graphics memory 530. The probing pad may be bonded to receive a power supply voltage of a specified level after the wafer level test is ended, and may be connected with a power supply voltage mesh in the graphics memory 530 to allow additional power to be supplied to the graphics memory 530.

While various embodiments have been described above, it will be understood to those skilled in the art that the embodiments described are examples only. Accordingly, the legal protection for the invention described herein should not be limited based on the described embodiments.

What is claimed is:

1. A memory apparatus comprising:
a pad;
an internal circuit that is connected with the pad;
a power connection unit connected with power meshes; and
a first switching unit suitable for selectively connecting the pad with the power connection unit based on a package control signal.

2. The memory apparatus according to claim 1, wherein the pad is bonded with a first power supply voltage terminal or a second power supply voltage terminal when the memory apparatus is packaged.

3. The memory apparatus according to claim 1, wherein the pad comprises an option pad for designating a data bandwidth of the memory apparatus.

4. The memory apparatus according to claim 1, wherein the pad comprises a probe pad for performing a test on the memory apparatus at a wafer level.

5. The memory apparatus according to claim 1, wherein the power connection unit is connected with a first power supply voltage mesh or a second power supply voltage mesh based on a signal, which is received through the pad and the first switching unit.

6. The memory apparatus according to claim further comprising:
a second switching unit suitable for selectively connecting the pad with an electrostatic discharge circuit based on the package control signal.

7. A memory apparatus comprising:
a first pad;
a first power switching unit suitable for connecting the first pad with a first power supply voltage mesh or a second power supply voltage mesh based on a signal, which is inputted through the first pad;
a second pad; and
a second power switching unit suitable for connecting the second pad with the first power supply voltage mesh or the second power supply voltage mesh based on a signal, which is inputted through the second pad.

8. The memory apparatus according to claim 7, wherein each of the first pad and the second pad comprises a bonding option pad for designating a data bandwidth of the memory apparatus.

9. The memory apparatus according to claim 7, wherein each of the first pad and the second pad comprises a probe pad for performing a test on the memory apparatus at a wafer level.

10. The memory apparatus according to claim 7, further comprising:
a first switching unit suitable for selectively connecting the first pad with a first electrostatic discharge circuit based on a package control signal; and
a second switching unit suitable for selectively connecting the second pad with a second electrostatic discharge circuit based on the package control signal.

11. A memory apparatus comprising:
a pad;
an internal circuit that uses a signal, which is received through the pad; and
a power switching unit suitable for connecting the pad with a first power supply voltage mesh or a second power supply voltage mesh based on the signal.

12. The memory apparatus according to claim 11, wherein the pad comprises a bonding option pad for designating a data bandwidth of the memory apparatus.

13. The memory apparatus according to claim 11, wherein the pad comprises a probe pad for performing a test on the memory apparatus at a wafer level.
